(19) United States
(12) Patent Application Publication
(10) Pub. No.: US 2026/0255884 A1
(43) Pub. Date: Aug. 27, 2026

(54) EMBEDDED MRAM DEVICE WITH AIR GAPS BETWEEN MTJ STRUCTURES

(71) Applicant: International Business Machines Corporation, Armonk, NY (US)

(72) Inventors: Shravana Kumar Katakam, Lehi, UT (US); Yann Mignot, Slingerlands, NY (US); Nitin Prasad, Guilderland, NY (US)

(21) Appl. No.: 19/060,078

(22) Filed: Feb. 21, 2025

(51) Int. Cl. H10N 50/80; G11C 11/16; H10N 50/10

(52) U.S. Cl. CPC H10N 50/80; G11C 11/161; H10N 50/10

(57) ABSTRACT

An embedded magnetoresistive random access memory (MRAM) device is provided in which a top metal contact composed of a subtractable etchable metal is in contact with a magnetic tunnel structure (MTJ) structure. An air gap is present surrounding the MTJ structure to reduce capacitance and enable the reduction of the RC (resistance-capacitance) time constant of the MRAM device at tight pitches.

### BACKGROUND

The present application relates to a memory device, and more particularly to an embedded magnetoresistive random access memory (MRAM) device including a top metal contact in contact with a magnetic tunnel junction (MTJ) structure, and an air gap that is located in a trench that is located adjacent to the MTJ structure.

MRAM is a non-volatile random access memory technology in which data is stored by magnetic storage elements. These elements are typically formed from two ferromagnetic plates, each of which can hold a magnetization, separated by a thin dielectric layer (i.e., a tunnel barrier layer). One of the two plates (i.e., the magnetic reference or pinned layer) is a magnet whose magnetic moment direction is set to a particular direction; the other plate's (i.e., the magnetic free layer's) magnetization can be changed in at least two different directions, representing different digital states such as 0 and 1 for memory applications. In MRAMs, such elements may be referred to as a MTJ pillar. In a typical MTJ pillar, the magnetization of the magnetic reference layer is fixed in one direction (say pointing up), while the direction of the magnetic free layer can be “switched” by some external forces, such as a magnetic field or a spin-torque generating charge current. A smaller current (of either polarity) can be used to read the resistance of the device, which depends on the relative orientations of the magnetizations of the magnetic free layer and the magnetic reference layer. The resistance is typically higher when the magnetizations are anti-parallel, and lower when they are parallel (though this can be reversed, depending on the material).

### SUMMARY

An embedded magnetoresistive random access memory (MRAM) device is provided in which a top metal contact composed of a subtractable etchable metal is in contact with a magnetic tunnel junction (MTJ) structure. An air gap is present surrounding the MTJ structure to reduce capacitance and enable the reduction of the RC (resistance-capacitance) time constant of the MRAM device at tight pitches.

In one embodiment of the present application, the embedded MRAM device includes a MTJ structure located on a substrate, an encapsulation spacer located along a sidewall of, and surrounding, the MTJ structure, a metal contact composed of a subtractive etchable metal located above, and in contact with, the MTJ structure, and an air gap located adjacent to the encapsulation spacer.

In another aspect of the present application, a structure is provided that includes the embedded MRAM device of the present application. Notably, the structure includes a logic device area including a first metal contact that is T-shaped, and a memory device area located adjacent to the logic device area, where the memory device area includes an embedded MRAM device in contact with a first metal structure of a substrate. The MRAM device includes at least one magnetic tunnel junction (MTJ) structure located on the substrate, an encapsulation spacer located along a sidewall of, and surrounding, the at least one MTJ structure, a second metal contact located above, and in contact with, the at least one MTJ structure, where the first metal contact and the second metal contact are composed of a subtractive etchable metal, and an air gap located adjacent to the encapsulation spacer.

### BRIEF DESCRIPTION OF THE DRAWINGS

FIG. 1 is a cross sectional view of an exemplary embedded MRAM device in accordance with an embodiment of the present application.

FIG. 2 is a cross sectional view of an exemplary structure that can be used in forming a structure that includes an embedded MRAM device in accordance with an embodiment of the present application, the exemplary structure includes a MTJ material containing stack located on a substrate.

FIG. 3 is a cross sectional view of the exemplary structure of FIG. 2 after patterning the MTJ material containing stack into at least one MTJ structure.

FIG. 4 is a cross sectional view of the exemplary structure of FIG. 3 after forming an encapsulation spacer adjacent to, and surrounding, the at least one MTJ structure.

FIG. 5 is a cross sectional view of the exemplary structure of FIG. 4 after forming a third interlayer dielectric (ILD) layer adjacent to, and above, the encapsulation spacer and the at least one MTJ structure; the substrate includes a first ILD layer and a second ILD layer.

FIG. 6 is a cross sectional view of the exemplary structure of FIG. 5 after removing the third ILD layer that is present in a memory device area, while maintaining the third ILD layer that is present in a logic device area.

FIG. 7 is a cross sectional view of the exemplary structure of FIG. 6 after forming a patterned mask having a via opening in the logic device area.

FIG. 8 is a cross sectional view of the exemplary structure of FIG. 7 after removing the patterned mask.

FIG. 9 is a cross sectional view of the exemplary structure of FIG. 8 after forming a metal layer.

FIG. 10 is a cross sectional view of the exemplary structure of FIG. 9 after performing a subtractive metal etching process of the metal layer to provide precursor metal contacts.

FIG. 11 is a cross sectional view of the exemplary structure of FIG. 10 after forming a fourth ILD layer that contains air gaps present therein.

FIG. 12 is a cross sectional view of the exemplary structure of FIG. 11 after performing a planarization process to convert the precursor metal contacts into metal contacts.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

The current top contact process has high top contact capacitances at tight pitches. It also has lower opens and short margins. An embedded MRAM device is provided in which a top metal contact composed of a subtractable etchable metal is in contact with a MTJ structure. An air gap is present surrounding the MTJ structure to reduce capacitance and enable the reduction of the RC (resistance-capacitance) time constant of the MRAM device at tight pitches. The air gap is spaced apart from the MTJ structure by an encapsulation spacer that also surrounds the MTJ structure. The use of a subtractable etchable metal reduces the depth loading across the macros and regions of the wafer improving the process window for opens and shorts.

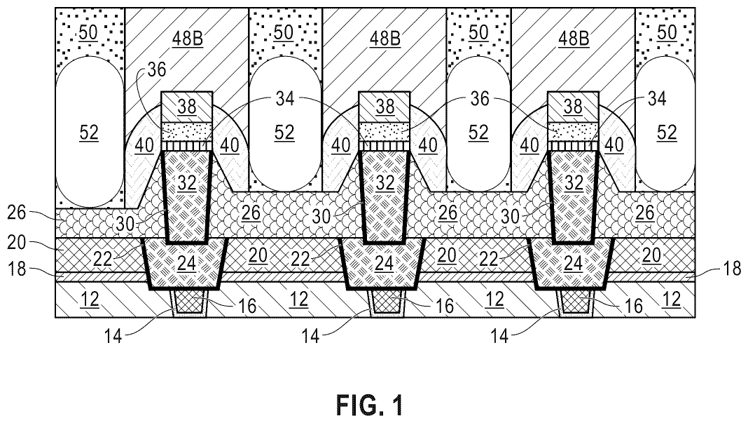

FIG. 1 illustrates an exemplary embedded MRAM device in accordance with an embodiment of the present application. Notably, the embedded MRAM device illustrated in FIG. 1 includes a MTJ structure located on a substrate, encapsulation spacer 40 located along a sidewall of, and surrounding, the MTJ structure, a metal contact (i.e., second metal contact 48B) composed of a subtractive etchable metal located above, and in contact with, the MTJ structure, and air gap 52 located adjacent to the encapsulation spacer 40. The air gap 52 surrounds the MTJ structure and provides the advantages mentioned above. The MTJ structure includes a MTJ pillar 36 located between a first (or bottom) electrode 34 and a second (or top) electrode 38. The MTJ pillar 36 includes a tunnel barrier layer (not separately illustrated) located between a magnetic free layer (not separately illustrated) and a magnetic reference (or pinned) layer (not separately illustrated).

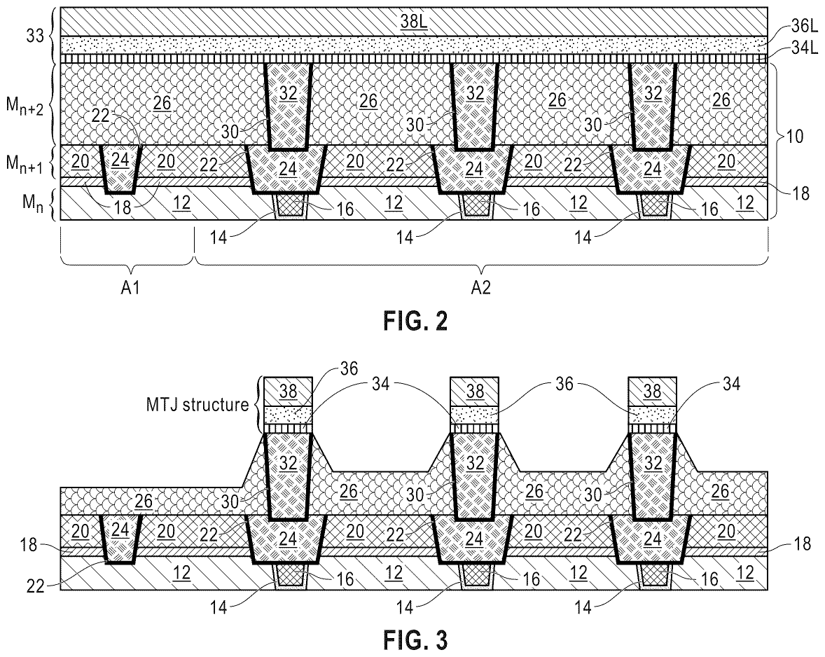

The substrate includes various metal levels containing metal structures (e.g., first metal structures 16, second metal structures 24 and third metal structures 32) embedded in various dielectric layers. The various dielectric layers of the substrate can include a first ILD layer 12, a second ILD layer 20, a first dielectric capping layer 18 and a second dielectric capping layer 26. The first dielectric capping layer 18 can be an optional layer of the substrate. The substrate will be better understood by referring to substrate 10 illustrated in FIG. 2 and described in further detail herein below.

In embodiments of the present application and as is illustrated in FIG. 1, the metal contact (i.e., second metal contact 48B) has a sidewall that is vertically aligned with a sidewall of the MTJ structure.

In embodiments of the present application and as is illustrated in FIG. 1, the encapsulation spacer 40 is located between the air gap 52 and the MTJ structure.

In embodiments of the present application and as is illustrated in FIG. 1, the air gap 52 extends along an entirety of a sidewall of the encapsulation spacer 40 and partially along a sidewall of the metal contact (i.e., second metal contact 48B).

In embodiments of the present application and as is illustrated in FIG. 1, the metal contact (i.e. second metal contact 48B) has a critical dimension that is greater than a critical dimension of the MTJ structure. In the present application, the critical dimension equals a width of a specific element/component.

In embodiments of the present application and as is illustrated in FIG. 1, the metal contact (i.e., second metal contact 48B) contacts a topmost surface and an upper portion of a sidewall of the MTJ structure. Notably, the metal contact (i.e., second metal contact 48B) contacts a topmost surface and an upper portion of sidewall of the second electrode 38 of the MTJ structure.

In embodiments of the present application and as is illustrated in FIG. 1, the metal contact (i.e. the second metal contact 48B) has a convex bottom surface that contacts a convex top surface of the encapsulation spacer 40.

Reference is now made to FIGS. 2-12 which illustrate a method of forming a structure including an embedded MRAM device in accordance with an embodiment of the present application; the illustrated method depicted in FIGS. 2-12 can be used in forming the embedded MRAM device illustrated in FIG. 1. Notably, FIG. 2 illustrates an exemplary structure (i.e., initial structure) that can be used in forming a structure including the embedded MRAM device of the present application. The exemplary structure illustrated in FIG. 1 includes a MTJ material containing stack 33 located on substrate 10. Substrate 10 can include a logic device area, A1, and a memory device area, A2. The logic device area, A1, includes an area in which logic devices and logic device interconnects are formed, and the memory device area, A2, is an area in which a memory device (e.g., the embedded MRAM device of the present application) and memory device interconnects are formed. In some embodiments, the logic device area, A1, can be omitted. Other types of device areas can be located adjacent to the device areas illustrated in FIG. 2.

In the present application, substrate 10 includes various metal levels including, for example, Mₙ, Mₙ₊₁ and Mₙ₊₂, where n is an integer (i.e., 0, 1, 2, 3, etc.). In the illustrated embodiment, n can be equal to 0. Although not illustrated in the drawings of the present application, the substrate 10 can be located on a front-end-of-the-line (FEOL) level that includes one or more semiconductor devices such as, for example, transistors, capacitors, resistors or any combination thereof, located on a surface of a semiconductor substrate. The FEOL level would be located beneath the lowest metal level present in substrate 10.

In the illustrated embodiment, Mₙ of substrate 10 includes a first interlayer dielectric (ILD) layer 12 that includes at least one first metal structure 16 embedded therein. In FIG. 2, three first metal structures 16 are shown by way of one example. Each first metal structure 16 is located in the memory device area, A2. In some embodiments, and as is illustrated in FIG. 2, each first metal structure 16 includes a first diffusion barrier liner 14 present along a sidewall and a bottommost surface of the first metal structure 16. The first diffusion barrier liner 14 is optional and need not be present in all embodiments of the present application.

In the illustrated embodiment, Mₙ₊₁ of substrate 10 includes a second ILD layer 20 that includes at least one second metal structure 24 embedded therein. In FIG. 2, and by way of one example, the substrate includes four second metal structures 24; one of the four second metal structures is present in the logic device area, A1, and three of the four second metal structures are present in the memory device area, A1. It is noted that the number of second metal structures 24 in the memory device area, A2, typically equals the number of first metal structures 16 present in the memory device area, A2. In the memory device area, A2, each second metal structure 24 is in electrical contact with an underlying first metal structure. This allows stacking and interconnect formation of the metal structures within substrate 10. In some embodiments, and as is illustrated in FIG. 2, each second metal structure 24 includes a second diffusion barrier liner 22 present along a sidewall and a bottommost surface of the second metal structure 24. The second diffusion barrier liner 22 is optional and need not be present in all embodiments of the present application. The critical dimension (or width) of each second metal structure 24 that is present in the memory device area, A2, can be the same as, or different from, the critical dimension (or width) of each first metal structure 16. In the embodiment illustrated in FIG. 2, each second metal structure 24 has a critical dimension (i.e., width) that is greater than the critical dimension (i.e., width) of each first metal structure 16.

In some embodiments and as is illustrated in FIG. 2, a first dielectric capping layer 18 can be located between M and Mₙ₊₁. In other embodiments, the first dielectric capping layer 18 can be omitted. When the first dielectric capping layer 18 is present, each second metal structure 24 extends entirely through the first dielectric capping layer 18.

In the illustrated embodiment, Mₙ₊₂ of substrate 10 includes a second dielectric capping layer 26 that includes third metal structure 32 embedded therein. Each third metal structure 32 is located in the memory device area. A2. In some embodiments, and as is illustrated in FIG. 2, each third metal structure 32 includes a third diffusion barrier liner 30 present along a sidewall and a bottommost surface of the third metal structure 32. The third diffusion barrier liner 30 is optional and need not be present in all embodiments of the present application. Each third metal structure 32 is in electrical contact with an underlying second metal structure. The number of third metal structures 32 present in the memory device area, A2, is typically equal to the number of second metal structures 24 present in the memory device area, A2. In the embodiment illustrated in FIG. 2, each third metal structure 32 is in electrically contact with a sub-surface of one of the underlying second metal structure 24. The term “sub-surface” denotes a surface of a material/structure that is located between a topmost surface and a bottommost surface of the same material/structure. The critical dimension (or width) of each third metal structure 32 that is present in the memory device area, A2, can be the same as, or different from, the critical dimension (or width) of each second metal structure 24. In the embodiment illustrated in FIG. 2, each third metal structure 32 has a critical dimension (i.e., width) that is lesser than the critical dimension (i.e., width) of each second metal structure 24.

The substrate 10 including Mₙ, Mₙ₊₁ and Mₙ₊₂ can be formed utilizing a damascene process in which openings are formed into a dielectric layer by lithography and etching and then each opening is processed by deposition, followed by planarization to include at least a metal structure. In embodiments, each opening can be processed to include a diffusion barrier liner and a metal structure.

In the present application, the first ILD layer 12 and the second ILD layer 20 are composed of a compositionally same, or different, ILD material. Exemplary ILD materials that can be used in providing the first ILD layer 12 and the second ILD layer 20 include, for example, silicon oxide (SiOₓ), silsesquioxanes, C doped oxides (i.e., organosilicates) that includes atoms of Si, C, O and H, thermosetting polyarylene ethers, or multilayers thereof. The term “polyarylene” is used in this application to denote aryl moieties or inertly substituted aryl moieties which are linked together by bonds, fused rings, or inert linking groups such as, for example, oxygen, sulfur, sulfone, sulfoxide, carbonyl and the like. The first ILD layer 12 and the second ILD layer 20 can have a dielectric constant (all dielectric constants mentioned herein are measured relative to a vacuum, unless otherwise stated) that is about 4.0 or less. In some embodiments, the dielectric can have a dielectric constant of 2.8 or less. These dielectrics generally having a lower parasitic cross talk as compared to dielectric materials whose dielectric constant is greater than 4.0.

The first dielectric capping layer 18 and the second dielectric capping layer 26 are composed of a compositionally same, or different, dielectric capping material. In the present application, the dielectric capping material is compositionally different from the ILD materials that provide the first ILD layer 12 and the second ILD layer 20. Exemplary dielectric capping materials that can be used in providing the first dielectric capping layer 18 and the second dielectric capping layer 26 include, but are not limited to, an NBLOK dielectric material that contains atoms of silicon, carbon, hydrogen, nitrogen and oxygen.

The first diffusion barrier liner 14, the second diffusion barrier liner 22 and the third diffusion barrier liner 30 are composed of a compositionally same, or different, diffusion barrier material. Exemplary diffusion barrier materials that can be used in providing the first diffusion barrier liner 14, the second diffusion barrier liner 22 and the third diffusion barrier liner 30 include, but are not limited to, Ta, TaN, Ti, TiN, W and/or WN. In some embodiments, the first diffusion barrier liner 14 and/or the second diffusion barrier liner 22 and/or the third diffusion barrier liner 30 is composed of a single diffusion barrier material. In other embodiments, the first diffusion barrier liner 14 and/or the second diffusion barrier liner 22 and/or the third diffusion barrier liner 30 is composed of a diffusion barrier material stack of two or more diffusion barrier materials. In one example, the first diffusion barrier liner 14 and/or the second diffusion barrier liner 22 and/or the third diffusion barrier liner 30 can be composed of a stack of Ta/TaN or a stack of Ti/TiN.

The first metal structure 16, the second metal structure 24 and the third metal structure 32 are composed of a compositionally same, or different, electrically conductive metal or electrically conductive metal alloy (collectively the electrically conductive metal or electrically conductive metal alloy can be referred to as an electrically conductive material). Illustrative examples of electrically conductive materials that can be used in the present application to provide first metal structure 16, the second metal structure 24 and the third metal structure 32 include, but are not limited to, Cu, Al, Cu—Al alloy, W, Ru, or Rh. The use of a diffusion barrier liner is directly related with the nature of the first metal structure 16, the second metal structure 24 and the third metal structure 32 and thus in some embodiments the diffusion barrier liner is not needed.

The MTJ material containing stack 33 that is located on substrate 10 includes a blanket layer of a first (or bottom) electrode material 34L, a MTJ stack 36L and a blanket layer of a second (or top) electrode material 38L. The blanket layer of the first electrode material 34L is composed of a first electrically conductive electrode material such as, for example, Ta, TaN, Ti, TiN, Ru, RuN, RuTa, RuTaN, Co, CoWP, CoN, W, WN or any combination thereof

The MTJ stack 36L includes a tunnel barrier layer (not specifically shown) that is sandwiched between a magnetic free layer (not specifically shown) and a magnetic reference (or pinned) layer (not specifically shown). In some embodiments, the MTJ stack 36L is a bottom pinned MTJ stack in which the magnetic reference (or pinned) layer is located beneath the tunnel barrier layer and the magnetic free layer is located above the tunnel barrier layer. In other embodiments, the MTJ stack 36L is a top pinned MTJ stack in which the magnetic free layer is located beneath the tunnel barrier layer and the magnetic reference (or pinned) layer is located above the tunnel barrier layer.

The MTJ material containing stack 33 can also include other layers (not specifically shown) such as, for example, a metal seed layer, a metal buffer layer, a metal spacer layer, a metal cap layer, or any combination of such layers.

The magnetic free layer of the MTJ stack 36L is composed of at least one magnetic material with a magnetization that can be changed in orientation relative to the magnetization orientation of a magnetic reference layer; note that the term “magnetic free layer” denotes that this magnetic layer has magnetization that can change (i.e., it does not have a fixed magnetization); the term does not however mean that this layer does not contain a magnetic material. Exemplary materials for the magnetic free layer include, but are not limited to, alloys and/or multilayers of cobalt, iron, alloys of cobalt-iron, nickel, alloys of nickel-iron, and alloys of cobalt-iron-boron. The magnetic free layer can have a thickness from 0.3 nm to 3 nm; although other thicknesses are possible and can be used as the thickness of the magnetic free layer. In some embodiments, the magnetic free layer can include a lower magnetic free layer and an upper magnetic free layer that are spaced apart by a metal spacer.

The tunnel barrier layer of the MTJ stack 36L is composed of an insulator material and is formed at such a thickness as to provide an appropriate tunneling resistance. Exemplary materials for the tunnel barrier layer include magnesium oxide, aluminum oxide, and titanium oxide, or materials of higher electrical tunnel conductance, such as semiconductors or low-bandgap insulators. The thickness of the tunnel barrier layer will depend on the material selected. In one example, the tunnel barrier layer can have a thickness from 0.5 nm to 1.5 nm; although other thicknesses are possible as long as the thickness of the tunnel barrier layer provides an appropriate tunneling resistance.

The magnetic reference (or pinned) layer of the MTJ stack 36L has a fixed magnetization. The magnetic reference (or pinned) layer is composed of a metal or metal alloy that includes one or more metals exhibiting high spin polarization. In alternative embodiments, exemplary metals for the formation of the magnetic reference (or pinned) layer include iron, nickel, cobalt, chromium, boron, and manganese. Exemplary metal alloys may include the metals exemplified by the above. In another embodiment, the magnetic reference (or pinned) layer may be a multilayer arrangement having (1) a high spin polarization region formed from of a metal and/or metal alloy using the metals mentioned above, and (2) a region constructed of a material or materials that exhibit strong perpendicular magnetic anisotropy (strong PMA). Exemplary materials with strong PMA that may be used include a metal such as cobalt, nickel, platinum, palladium, iridium, or ruthenium, and may be arranged as alternating layers. The strong PMA region may also include alloys that exhibit strong PMA, with exemplary alloys including cobalt-iron-terbium, cobalt-iron-gadolinium, cobalt-chromium-platinum, cobalt-platinum, cobalt-palladium, iron-platinum, and/or iron-palladium. The alloys may be arranged as alternating layers. In one embodiment, combinations of these materials and regions may also be employed. The magnetic reference (or pinned) layer can have a thickness from 0.3 nm to 3 nm; although other thicknesses are possible and can be used as the thickness of the magnetic reference (or pinned) layer.

The blanket layer of the second electrode material 38L is composed of a second electrically conductive electrode material such as, for example, Ta, TaN, Ti, TiN, Ru, RuN, RuTa, RuTaN, Co, CoWP, CoN, W, WN or any combination thereof. The second electrically conductive electrode material that provides the blanket layer of the second electrode material 38L can be compositionally the same as, or compositionally different from, the first electrically conductive electrode material that provides the blanket layer of the first electrode material 34L.

The MTJ material containing stack 33 including the blanket layer of the first electrode material 34L, the MTJ stack 36L and the blanket layer of the second electrode material 38L can be formed utilizing one or more deposition processes. The one or more deposition processes that can be used in forming the MTJ material containing stack 33 include, but are not limited to, chemical vapor deposition (CVD), plasma enhanced chemical vapor deposition (PECVD), atomic layer deposition (ALD) or plasma enhanced atomic layer deposition (PE-ALD).

Referring now to FIG. 3, there is illustrated the exemplary structure of FIG. 2 after patterning the MTJ material containing stack 33 into at least one MTJ structure; in the illustrated embodiment three MTJ structures are shown by way of one example. The MTJ structures are located in the memory area, A2. In the present application, a MTJ structure includes at least a first (or bottom) electrode 34, a MTJ pillar 36 and a second (or top) electrode 38. The patterning of the MTJ material containing stack 33 includes lithographic patterning. Lithography patterning includes forming a patterned photoresist by deposition of a photoresist material, exposing the as-deposited photoresist material to a desired pattern of irradiation and developing the exposed photoresist material. The lithography patterning continues utilizing an etching process to transfer the patterned provided by the patterned photoresist into the underlying MTJ material containing stack 33. Notably, the etching process removes portions of the MTJ material containing stack 33 that are not protected by the patterned photoresist. The etching process can include reactive ion etching (RIE), ion beam etching (IBE) or a combination of RIE and IBE. The patterned photoresist can be removed anytime during this pattern transfer process. In one example, the patterned photoresist is removed after the pattern has been transferred into the blanket layer of the second electrode material 38L. In such an embodiment, the non-etched portion of the blanket layer of the second electrode material 38L is referred to as the second electrode 38, and the second electrode 38 is then used as a hard mask during the remaining pattern transfer (i.e., etching) process.

As mentioned above, the non-etched portion of the blanket layer of the second electrode material 38L is referred to as the second electrode 38. The non-etched portion of the MTJ stack 36L is referred as the MTJ pillar 36, and the non-etched portion of the blanket layer of the first electrode material 34L is referred to as the first electrode 34. Each MTJ pillar 36 includes at least a non-etched portion of the magnetic free layer, a non-etched portion of the tunnel barrier layer and a non-etched portion of the magnetic reference (or pinned) layer.

It is noted that the etching process used in forming each MTJ structure stops on a surface of the second dielectric capping layer 26. In some embodiments (not shown), the etching process stops on a topmost surface of the second dielectric capping layer 26. In other embodiments (and as illustrated in FIG. 3), the etching process stops on a sub-surface surface of the second dielectric capping layer 26. It is noted that the etching process does not etch any portion of the third metal structure 32 and as such no metal particles from the third metal structure re-sputter onto the sidewall of the MTJ structure during the patterning process. As such, a portion of the second dielectric capping layer 26 surrounds and entirety of the third metal structure 32.

Within each MTJ structure, the second electrode 38 has a sidewall that is vertically aligned with a sidewall of the MTJ pillar 36 and a sidewall of the first electrode 34. Each MTJ structure is typically, but necessity always, cylindrical in shape. Each MTJ structure has a critical dimension that is equal to, or greater than, a critical dimension of the third metal structure 32. As is illustrated, the first electrode 34 of the MTJ structure is in contact with an underlying third metal structure.

Each MTJ structure is spaced apart from each other by a pitch from 30 nm to 500 nm, with a pitch from 100 nm to 200 nm being more typical. The term “pitch” is a measurement from one point of a structure (e.g., a central point of the structure) to the same point on a nearest neighbor structure.

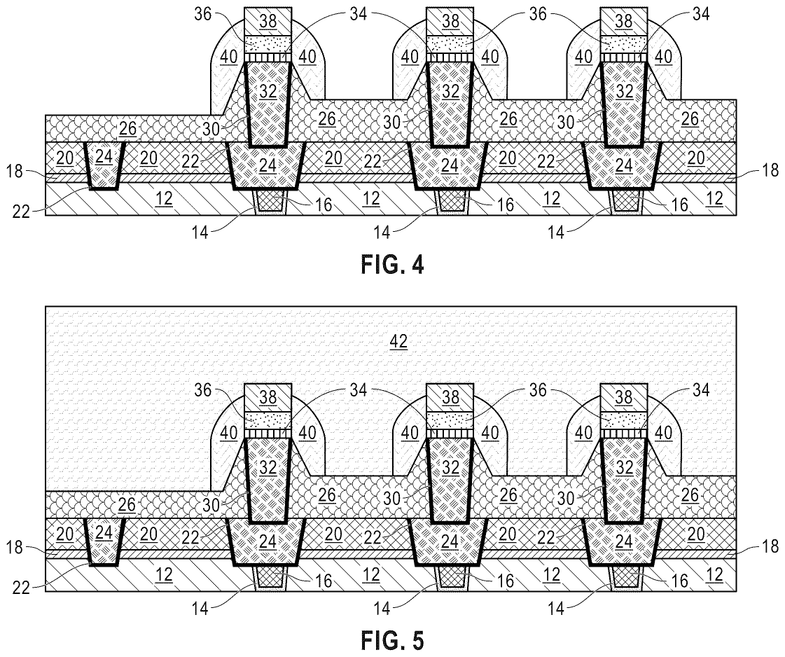

Referring now to FIG. 4, there is illustrated the exemplary structure of FIG. 3 after forming an encapsulation spacer 40 adjacent to, and surrounding, the at least one MTJ structure. The encapsulation spacer 40 can be composed of any dielectric material that can be used to encapsulation, and in some instances, passivate, the MTJ structure. The dielectric material that provides the encapsulation spacer 40 is typically compositionally different from the second dielectric capping layer 26. In some embodiments, the dielectric material that provides the encapsulation spacer 40 includes atoms of silicon, carbon and hydrogen (i.e., a SiCH containing dielectric). In other embodiments, and in addition to atoms of carbon and hydrogen, the dielectric material that provides the encapsulation spacer 40 can include atoms of at least one of nitrogen and oxygen. In still other embodiments, and in addition to atoms of silicon, nitrogen, carbon and hydrogen, the dielectric material that provides the encapsulation spacer 40 can include atoms of boron. In one example, the dielectric material that provides the encapsulation spacer 40 can be composed of an NBLOK dielectric material that contains atoms of silicon, carbon, hydrogen, nitrogen and oxygen. In alternative example, the dielectric material that provides the encapsulation spacer 40 can be composed of a SiBCN dielectric material that contains atoms of silicon, boron, carbon, hydrogen, and nitrogen. The encapsulation spacer 40 can be formed utilizing a deposition process such, as, for example, CVD, PECVD, ALD or spin-on coating, followed by an etch back process.

The encapsulation spacer 40 is present on a sidewall of the MTJ structure and has a bottom surface that lands on a surface of the second dielectric capping layer 26. Notably, the encapsulation spacer 40 covers an entirety of the sidewall of the first electrode 34 and the sidewall of the MTJ pillar 36 and the encapsulation spacer 40 covers at least a lower portion of the sidewall of the second electrode 38. In the illustrated embodiment of FIG. 4, the encapsulation spacer 40 is absent from a top portion of the sidewall of the second electrode 38. The encapsulation spacer 40 typically has a convex top surface as is illustrated in FIG. 4. The encapsulation spacer 40 is spaced apart from the third metal structure 32 by a portion of the second dielectric capping layer 26 that surrounds that third metal structure 32.

Referring now to FIG. 5, there is illustrated the exemplary structure of FIG. 4 after forming a third ILD layer 42 adjacent to, and above, the encapsulation spacer 40 and the at least one MTJ structure. The third ILD layer 42 includes one of the ILD materials mentioned above for the first ILD layer 12 and the second ILD layer 20. The ILD material that provides the third ILD layer 42 can be compositionally the same as, or compositionally different from, the ILD material that provides the first ILD layer 12 and/or the second ILD layer 20. The third ILD layer 42 can be formed by a deposition process including, for example, CVD, PECVD or spin-on coating. The third ILD layer 42 that is formed is air gap free.

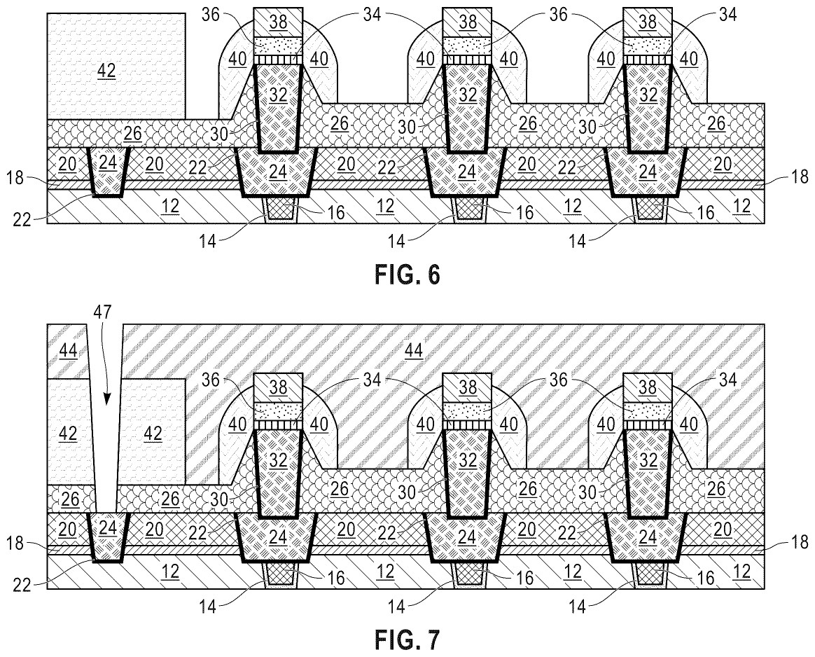

Referring now to FIG. 6, there is illustrated the exemplary structure of FIG. 5 after removing the third ILD layer 42 that is present in the memory device area, A2, while maintaining the third ILD layer 42 that is present in the logic device area, A1. The removal of the third ILD layer 42 that is present in the memory device area, A2, while maintaining the third ILD layer 42 that is present in the logic device area, A1, includes a lithographic patterning process as mentioned above. Notably, a patterned photoresist is formed above the third ILD layer 42 in the logic device area, A1, and an etch is then used to remove the third ILD layer 42 from the memory device area, A2. In embodiments in which the logic device area, A1, is not present, the forming of the third ILD layer 42 and the subsequent patterning thereof can be omitted.

Referring now to FIG. 7, there is illustrated the exemplary structure of FIG. 6 after forming a patterned mask 44 having a via opening 47 in the logic device area, A1. The patterned mask 44 is formed in both the logic device area, A1, and the memory device area, A2. The patterned mask 44 is defined utilizing a photoresist and antireflective coating layer that are not shown as they have been removed during the forming of the via opening 47. The patterned mask 44 is composed of an organic planarization material. The patterned mask 44 can be formed by deposition of the organic planarization material utilizing CVD, PECVD, ALD, physical vapor deposition (PVD) or spin-coating, followed by lithographic patterning. The via opening 47 can be formed by etching where the etching extends from the topmost surface of the patterned mask 44 to a topmost surface of the second metal structure 24 that is present in the logic device area, A1. The etching removes portions of the patterned mask 44, the third ILD layer 42, and the second dielectric capping layer 26 that are present in the logic device area, A1. This step of the present application can be omitted when no logic device area, A1, is present.

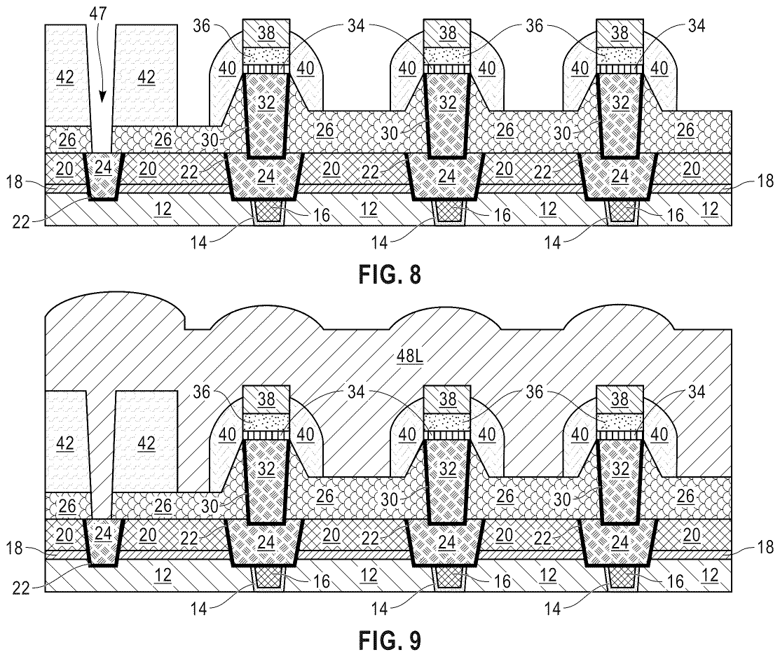

Referring now to FIG. 8, there is illustrated the exemplary structure of FIG. 7 after removing the patterned mask 44. The removal of the patterned mask 44 includes a material removal process that is capable of removing the patterned mask 44 from the structure. In one embodiment, the patterned mask 44 is removed by etching after via opening 47 formation.

Referring now to FIG. 9, there is illustrated the exemplary structure of FIG. 8 after forming a metal layer 48L. In the logic device area, A1, the metal layer 48L is formed in the via opening 47 and on top of the third ILD layer 42. In the memory device area, A2, the metal layer 48L is formed in the trench (i.e., space) that is located between each of the MTJ structures and above each of the MTJ structures. Metal layer 48L is composed of a subtractive etchable metal. By “subtractive etchable metal” it is meant a metal that can be etched utilizing anisotropic etching. Anisotropic etching is a process that selectively removes a material from a substrate in specific directions, allowing for the creation of well-defined features with sharp corners and edges. Unlike isotropic etching, which removes material uniformly in all directions, anisotropic etching responds to specific directions. Exemplary subtractive etchable metals that can be used in the present application as metal layer 48L include, but are not limited to, Ru, Mo, Al, W or Cu. In some embodiments, the subtractive etchable metal is a metal other than Cu. The metal layer 48L can be formed by a deposition process including, but not limited to, CVD, PECVD, PVD, ALD, or sputtering.

The metal layer 48L has a topography that mimics the underlying topography of the exemplary structure illustrated in FIG. 8 (i.e., the structure prior to metal layer 48L formation). The metal layer 48L has hills and valleys as illustrated in FIG. 9. In some embodiments in which the topography of the metal layer 48L is sufficient, the metal layer 48L can be used for alignment purposes in subsequent step processing steps. Planarization of metal layer 48L is obtained with the optimal thickness about the MTJ structure and over the third ILD layer 42. A final planarization, CMP, can be applied for better uniformity and avoid mask puddling.

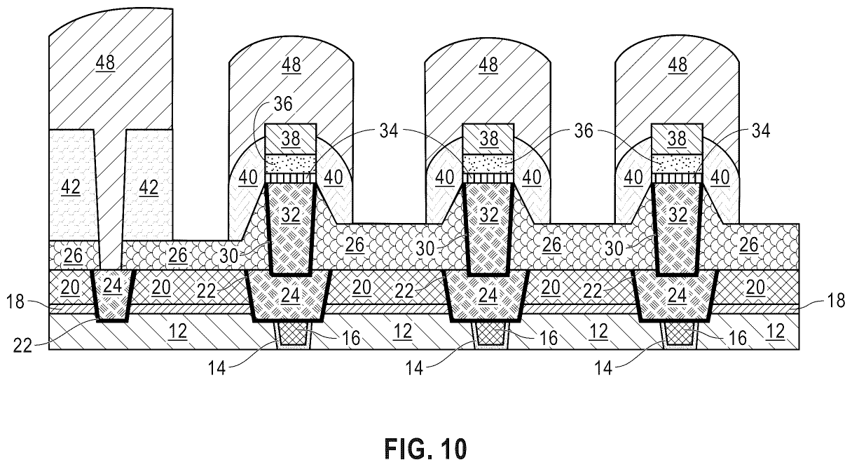

Referring now to FIG. 10, there is illustrated the exemplary structure of FIG. 9 after performing a subtractive metal etching process of the metal layer 48L to provide precursor metal contacts 48. The subtractive metal etching process includes forming a patterned mask (not shown) on top of the metal layer 48L. The patterned mask has openings therein in areas that are located adjacent to each of the MTJ structures. The patterned mask can be formed utilizing techniques well known to those skilled in the art and is removed after the precursor metal contacts 48 are formed. After forming the patterned mask, the subtractive metal etching process continues by performing an anisotropic etching process utilizing the patterned mask as an etch mask. The anisotropic etching process removes the metal layer 48L that is located in the trench (i.e., space) that is located between each of the MTJ structures. In the logic device area, A1, the metal layer 48L that remains after the anisotropic etch is located in the via opening 47 and on top of the third ILD layer 42. In the memory device area, A2, the metal layer 48L that remains after the anisotropic etch is located above the MTJ structure and the encapsulation spacer 40. The metal layer 48L that remains after the anisotropic etch is referred to the precursor metal contacts 48. In the logic device area, A1, the precursor metal contact 48 has a sidewall that is vertically aligned to a sidewall of the third ILD layer 42. In the memory device area, A2, the precursor metal contact 48 has a sidewall that is vertically aligned to a sidewall of the encapsulation spacer 40.

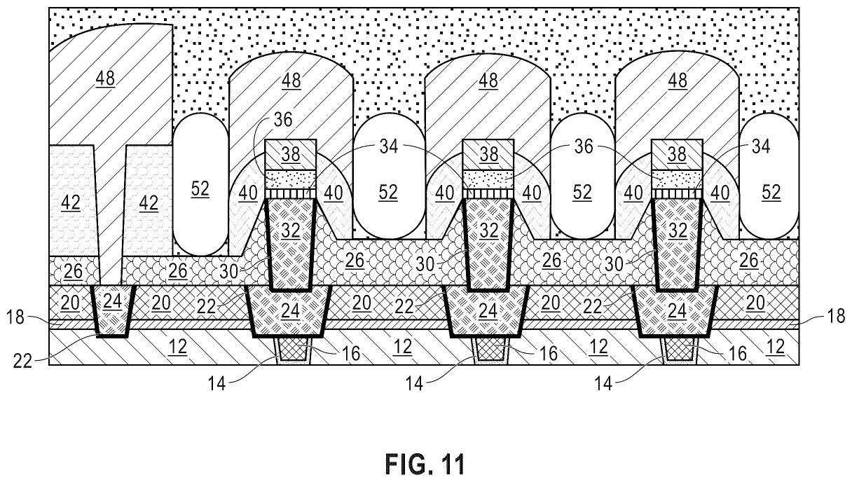

Referring now to FIG. 11, there is illustrated the exemplary structure of FIG. 10 after forming a fourth ILD layer 50 that contains air gaps 52 present therein. The air gaps 52 are located in the trench (i.e., space) that that is located between each of the MTJ structures. The fourth ILD layer 50 includes one of the ILD materials mentioned above for the first ILD layer 12 and the second ILD layer 20. The ILD material that provides the fourth ILD layer 50 can be compositionally the same as, or compositionally different from, the ILD material that provides the first ILD layer 12 and/or the second ILD layer 20 and/or third ILD layer 42. The fourth ILD layer 50 can be formed by a deposition process including, for example, CVD, PECVD or spin-on coating.

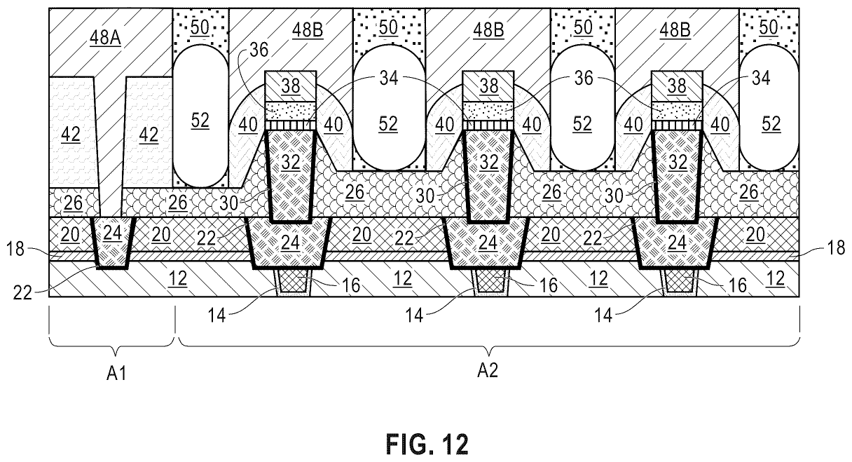

Referring now to FIG. 12, there is illustrated the exemplary structure of FIG. 11 after performing a planarization process to convert the precursor metal contacts 48 into metal contacts. Notably, a first metal contact 48A is formed that is in electrical contact with the second metal structure 24 that is present in the logic device area, A1, and second metal contacts 48B are formed in the memory device area, each second metal contact is located above each MTJ structure/encapsulation spacer 40 combination. The first metal contact 48A is T-shaped. The second metal contacts 48B non T-shaped. Each second metal contact 48B is in electrically contact with the second electrode 38 of one of the MTJ structures. In some embodiments, each second metal contact 48B directly contacts a topmost surface and an upper portion of a sidewall of the second electrode 38 of one of the MTJ structures. The planarization process includes CMP or grinding. The first and second contact structures have topmost surfaces that are substantially coplanar with each other. In the present application, each of the air gaps 52 extend along an entirety of a sidewall of the encapsulation spacer 40 and partially along a sidewall of a metal contact (e.g., second metal contacts 48B).

In the logic device area, A1, the first metal contact 48A has a sidewall that is vertically aligned to a sidewall of the third ILD layer 42. In the memory device area, A2, the second metal contact 48B has a sidewall that is vertically aligned to a sidewall of the encapsulation spacer 40. As is illustrated in FIG. 12, the air gaps 52 in the memory device area, A2, contact a sidewall of the encapsulation spacer 40 and the second metal contact 48B that is located above the MTJ structure. Each second metal contact 48B has a critical dimension that is greater than a critical dimension of the MTJ structure. Each second metal contact 48B has a convex bottom surface that contacts the convex top surface of the encapsulation spacer 40. In the present application, the second metal contact 48B can contact an upper portion of the sidewall of the MTJ structure as well as a topmost surface of the MTJ structure.

Notably, FIG. 12 illustrates a structure that includes logic device area, A1, including first metal contact 48A that is T-shaped, and a memory device area, A2, located adjacent to the logic device area, A1, where the memory device area, A2, includes an embedded MRAM device in contact with a first metal structure 16 of substrate 10. The MRAM device includes at least MTJ structure located on the substrate 10, an encapsulation spacer 40 located along a sidewall of, and surrounding, the at least one MTJ structure, a second metal contact 48B located above, and in contact with, the at least one MTJ structure, where the first metal contact 48A and the second metal contact 48B are composed of a subtractive etchable metal, and air gap 52 located adjacent to the encapsulation spacer 40. The air gap 52 surrounds the MTJ structure and provides reduced capacitance and a reduction of the RC time constant.

In embodiments of the present application, the least one MTJ structure includes MTJ pillar 36 located between first electrode 34 and second electrode 38. The MTJ pillar 36 can include a tunnel barrier layer located between a magnetic free layer and a magnetic reference layer.

In embodiments of the present application and as illustrated in FIG. 12, the second metal contact 48B has a sidewall that is vertically aligned with a sidewall of the at least one MTJ structure.

In embodiments of the present application and as illustrated in FIG. 12, the encapsulation spacer 40 is located between the air gap 52 and the at least one MTJ structure.

In embodiments of the present application and as illustrated in FIG. 12, the substrate 10 in the memory device area, A2, further includes a second metal structure 24 and a third metal structure 32, where the second metal structure 24 is located between, and in contact with, the first metal structure 16, and the third metal structure 32 is in contact with a bottom surface of the MTJ structure.

In embodiments of the present application and as illustrated in FIG. 12, the air gap 52 extends along an entirety of a sidewall of the encapsulation spacer 40 and partially along a sidewall of the second metal contact 48B.

In embodiments of the present application and as illustrated in FIG. 12, the second metal contact 48B has a critical dimension that is greater than a critical dimension of the at least one MTJ structure.

In embodiments of the present application and as illustrated in FIG. 12, the second metal contact 48B contacts a topmost surface and an upper portion of a sidewall of the at least one MTJ structure.

In embodiments of the present application and as illustrated in FIG. 12, the second metal contact 48B has a convex bottom surface that contacts a convex top surface of the encapsulation spacer 40.

In embodiments of the present application and as illustrated in FIG. 12, the air gap 52 is located between the logic device area, A1, and the memory device area, A2.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. An embedded magnetoresistive random access memory (MRAM) device comprising:
a magnetic tunnel junction (MTJ) structure located on a substrate;
an encapsulation spacer located along a sidewall of, and surrounding, the MTJ structure;
a metal contact composed of a subtractive etchable metal located above, and in contact with, the MTJ structure; and
an air gap located adjacent to the encapsulation spacer.

2. The embedded MRAM device of claim 1, wherein the MTJ structure comprises a MTJ pillar located between a first electrode and a second electrode, and the MTJ pillar comprises a tunnel barrier layer located between a magnetic free layer and a magnetic reference layer.

3. The embedded MRAM device of claim 1, wherein the metal contact has a sidewall that is vertically aligned with a sidewall of the MTJ structure.

4. The embedded MRAM device of claim 1, wherein the encapsulation spacer is located between the air gap and the MTJ structure.

5. The embedded MRAM device of claim 1, wherein the substrate comprises at least one metal structure, and the at least one metal structure is in contact with a bottom surface of the MTJ structure.

6. The embedded MRAM device of claim 1, wherein the substrate comprises a first metal structure, a second metal structure and a third metal structure, wherein the second metal structure is located between, and in contact with, the first metal structure and the second metal structure, and the third metal structure is in contact with a bottom surface of the MTJ structure.

7. The embedded MRAM device of claim 1, wherein the air gap extends along an entirety of a sidewall of the encapsulation spacer and partially along a sidewall of the metal contact.

8. The embedded MRAM device of claim 1, wherein the metal contact has a critical dimension that is greater than a critical dimension of the MTJ structure.

9. The embedded MRAM device of claim 1, wherein the metal contact contacts a topmost surface and an upper portion of a sidewall of the MTJ structure.

10. The embedded MRAM device of claim 1, wherein the metal contact has a convex bottom surface that contacts a convex top surface of the encapsulation spacer.

11. A structure comprising:
a logic device area comprising a first metal contact; and
a memory device area located adjacent to the logic device area, wherein the memory device area comprises an embedded magnetoresistive random access memory (MRAM) device in contact with a first metal structure of a substrate, wherein the MRAM device comprises:
at least one magnetic tunnel junction (MTJ) structure located on the substrate;
an encapsulation spacer located along a sidewall of, and surrounding, the at least one MTJ structure;
a second metal contact located above, and in contact with, the at least one MTJ structure, wherein the first metal contact and the second metal contact are composed of a subtractive etchable metal; and
an air gap located adjacent to the encapsulation spacer.

12. The structure of claim 11, wherein the at least one MTJ structure comprises a MTJ pillar located between a first electrode and a second electrode, and the MTJ pillar comprises a tunnel barrier layer located between a magnetic free layer and a magnetic reference layer.

13. The structure of claim 11, wherein the second metal contact has a sidewall that is vertically aligned with a sidewall of the at least one MTJ structure.

14. The structure of claim 11, wherein the encapsulation spacer is located between the air gap and the at least one MTJ structure.

15. The structure of claim 11, wherein the substrate in the memory device area further comprises a second metal structure and a third metal structure, wherein the second metal structure is located between, and in contact with, the first metal structure and the second metal structure, and the third metal structure is in contact with a bottom surface of the MTJ structure.

16. The structure of claim 11, wherein the air gap extends along an entirety of a sidewall of the encapsulation spacer and partially along a sidewall of the second metal contact.

17. The structure of claim 11, wherein the second metal contact has a critical dimension that is greater than a critical dimension of the at least one MTJ structure.

18. The structure of claim 11, wherein the second metal contact contacts a topmost surface and an upper portion of a sidewall of the at least one MTJ structure.

19. The structure of claim 11, wherein the second metal contact has a convex bottom surface that contacts a convex top surface of the encapsulation spacer.

20. The structure of claim 11, wherein the air gap is located between the logic device area and the memory device area.
